(19) United States
(12) Patent Application Publication
(10) Pub. No.: US 2005/0280016 A1
(43) Pub. Date: Dec. 22, 2005

(54) PCB-based surface mount LED device with silicone-based encapsulation structure

(76) Inventors: Thye Linn Mok, Penang (MY); Ju Chin Poh, Johor (MY); Siew It Pang, Penang (MY); Cheng Pei Chang, Dedah (MY)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/870,362

(22) Filed: Jun. 17, 2004

(51) Int. Cl. H01L 29/22

(52) U.S. Cl. 257/99

(57) ABSTRACT

A light emitting device includes a PCB substrate, an LED die that is attached to the PCB substrate, and a silicone-based encapsulation structure that encapsulates the LED die between the silicone-based encapsulation structure and the PCB substrate. The silicone-based material that is used to form the encapsulation structure exhibits low moisture absorption and a low elastic modulus relative to epoxy-based materials.

### BACKGROUND OF THE INVENTION

Printed circuit board (PCB) assemblies using surface mount technology are now common and surface mount light emitting diode (LED) devices are being used on these PCB assemblies. The surface mount LED devices are mass-produced on PCB substrates which are then surface mounted to the PCB assemblies. Typical PCB-based surface mount LED devices use optical grade epoxy materials to encapsulate the LED die and conductive wire. Although optical grade epoxy materials are widely used, they exhibit moisture absorption and elastic modulus characteristics which can make it difficult to pass industry standard performance tests, such as the moisture sensitivity test that is defined by the Joint Electron Device Engineering Council (JEDEC) Solid State Technology Association, and known as the JEDEC moisture sensitivity level (MSL) 1 test. The JEDEC MSL 1 test involves measuring LED device performance under conditions (e.g., humidity and temperature) that are similar to those found in the solder reflow processes used in surface mounting. Specifically, the JEDEC MSL 1 test involves soaking an LED device in 85% relatively humidity at 85 degrees Celsius for 168 hours and then subjecting the LED device to three solder reflow processes. A disadvantage to using optical grade epoxy encapsulation materials in PCB-based surface mount LED devices is that moisture diffuses into the LED package during the soaking and causes “popcorn” effects, which damage the interconnection areas when the temperature rises suddenly as a result of the solder reflow process.

In view of this, what is needed is a surface mount LED device with acceptable optical properties that performs well in industry standard performance tests.

### SUMMARY OF THE INVENTION

A light emitting device according to the invention includes a PCB substrate, an LED die that is attached to the PCB substrate, and a silicone-based encapsulation structure that encapsulates the LED die between the silicone-based encapsulation structure and the PCB substrate. The silicone-based material that is used to form the encapsulation structure exhibits low moisture absorption and a low elastic modulus relative to epoxy-based materials. These performance characteristics make it possible for PCB-based surface mount LED devices with silicon-based encapsulation structures to pass the JEDEC MSL 1 test on a more consistent basis than PCB-based surface mount LED devices with epoxy-based encapsulation structures.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 depicts a printed circuit board (PCB) based surface mount light emitting diode (LED) device according to the invention.

FIG. 2 depicts an example of a PCB-based surface mount LED device with a silicone-based encapsulation structure that has a flat top surface and a separate lens structure.

FIG. 3 depicts an example of a PCB matrix with insulating material, conductors, and die pads.

FIG. 4 depicts LED die attached to the die pads of the PCB matrix from FIG. 3 and conductive wires bonded between the LED die and the conductors.

FIG. 5 depicts an example of PCB-based surface mount LED devices with silicone-based encapsulation structures, where the encapsulation structures include lens structures.

FIG. 6 depicts an example of PCB-based surface mount LED devices with silicone-based encapsulation structures, where the encapsulation structures do not include an integrated lens.

FIG. 7 depicts an example of the PCB-based surface mount LED devices from FIG. 6 in which lens structures have been attached on top of the silicone-based encapsulation structures.

FIG. 8 depicts the PCB-based surface mount LED devices from FIG. 5 or 7 after the LED devices are separated from each other into individual devices.

Throughout the description similar reference numbers may be used to identify similar elements.

### DETAILED DESCRIPTION

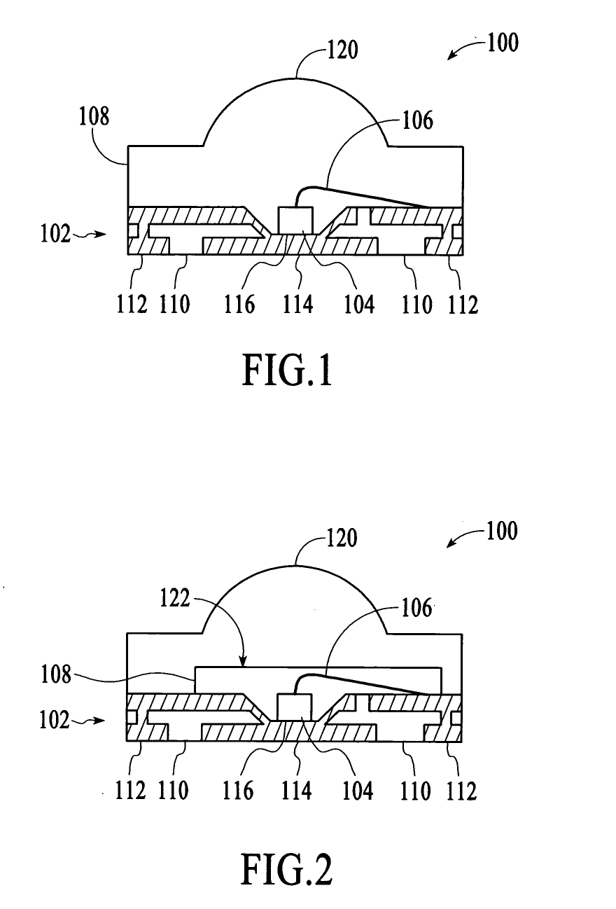

A light emitting device according to the invention includes a PCB substrate, an LED die that is attached to the PCB substrate, and a silicone-based encapsulation structure that encapsulates the LED die between the silicone-based encapsulation structure and the PCB substrate. FIG. 1 depicts a printed circuit board (PCB) based surface mount light emitting diode (LED) device 100 according to the invention. The PCB-based surface mount LED device includes a PCB substrate 102, an LED die 104, a conductive wire 106, and a silicone-based encapsulation structure 108.

The PCB substrate 102 includes insulating material 110 and conductors 112 (referred to herein as “leads”). The insulating material electrically separates two leads that enable current to flow through the LED die 104 as is well known in the field. Exposed portions of the two leads are formed to be compatible with surface mount technology and are referred to herein as surface mount-compatible leads. A portion 114 of one of the conductors may be located directly beneath the LED die to serve as a heat sink as is known in the field. The portion of the surface mount-compatible leads that are surface mounted to another structure, such as a circuit board may be, for example, L-wing, J-wing, or G-wing leads as is known in the field.

The LED die 104 is a semiconductor-based LED that is attached to the PCB substrate 102 using known techniques. The LED die is electrically connected to one of the leads 112 of the PCB substrate via a direct connection to the lead (e.g., a conductive bond to a die pad 116) and to the other one of the leads through the conductive wire 106, which is bonded between the LED die and the respective lead. The conductive wire creates an interconnection between the die and the respective lead and the area around the conductive wire and the associated wire bonds is referred to herein as the “interconnection area.” The two conductive leads, the conductive wire, and the LED die create a conductive circuit through which the LED die can be biased. When biased, the LED die emits light as is known in the field.

The silicone-based encapsulation structure 108 is created over the LED die 104 and is configured to completely encapsulate the LED die between the encapsulation structure and the PCB substrate 102. The encapsulation structure also encapsulates the conductive wire 106 and the associated wire bonds. The encapsulation structure can be formed through dispensing, casting, or molding. Some silicone-based materials require application of a silicone primer on the surfaces that are to be covered by the silicon-based material. Because light that is emitted from the LED die must pass through the silicone-based encapsulation structure, the silicone-based material that is used to form the encapsulation structure must be an optical grade material that has a refractive index of 1.4 or greater and a transmissivity of 90% or greater. Ideally, the silicone-based material is optically transparent, having a transmissivity of 100%.

Additional performance characteristics of the silicone-based material are low moisture absorption (e.g., less than 0.2%) and a low elastic modulus (e.g., less than 100 mega-Pascals (MPa)). These performance characteristics reduce the amount of moisture that diffuses into the interconnection area and reduce thermal induced stress on the conductive wire and the wire bonds as compared to traditional epoxy-based encapsulation structures. The above-described performance characteristics of the silicone-based material make it possible for PCB-based surface mount LED devices with silicon-based encapsulation structures to pass the JEDEC MSL 1 test on a more consistent basis than PCB-based surface mount LED devices with epoxy-based encapsulation structure.

Because silicone-based materials are more resistant to heat (that is, they absorb less moisture and create less mechanical stress in response to excessive heat than epoxy-based materials), a PCB-based surface mount LED device with a silicone-based encapsulation structure can be driven harder to produce more light than an epoxy-based counterpart. Further, the performance characteristics of the silicone-based material allow PCB-based surface mount LED devices with silicone-based encapsulation structures to be used in outdoor applications that demand greater resistance to humidity and high temperatures than controlled environment applications.

In the embodiment of FIG. 1, the silicone-based encapsulation structure 108 includes a lens structure 120 for manipulating the light that is emitted from the LED die. For example, the lens is configured as a dome to focus and direct the emitted light. In another embodiment, the silicone-based encapsulation structure does not include an integrated lens. For example, the silicone-based encapsulation structure is configured with a flat top surface. FIG. 2 depicts an example of a PCB-based surface mount LED device 100 with a silicone-based encapsulation structure 108 that has a flat top surface 122. Because the flat top surface does not significantly focus the light that is emitted from the LED die, a lens structure 124 is attached over top of the silicone-based encapsulation structure to focus the light. The lens structure could be, for example, a plastic lens that is attached to the top of the PCB-based surface mount LED device. The lens structure can be formed by, for example, using known molding or casting techniques.

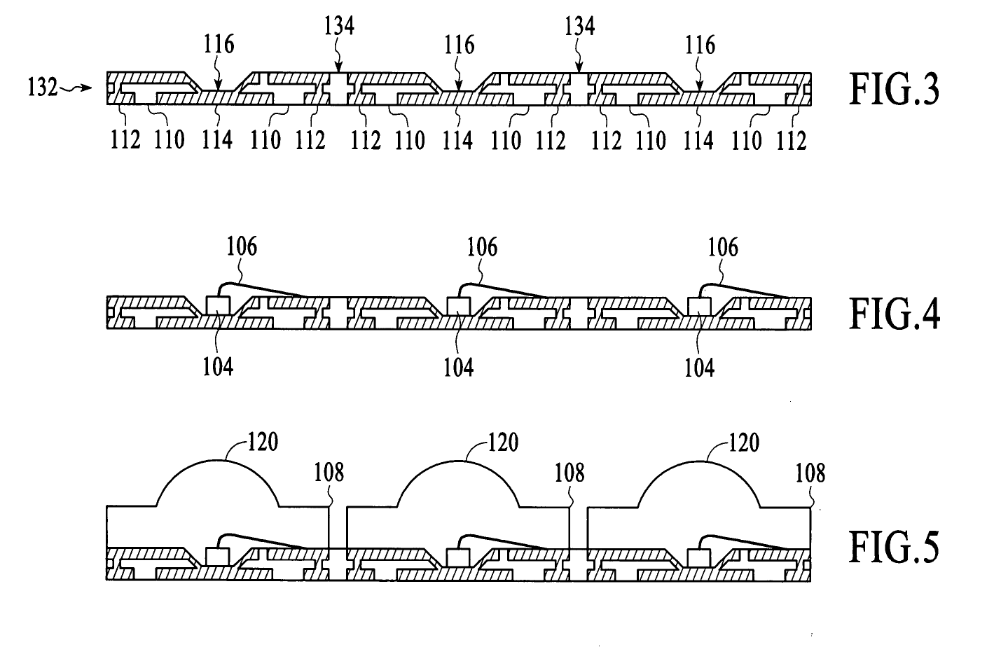

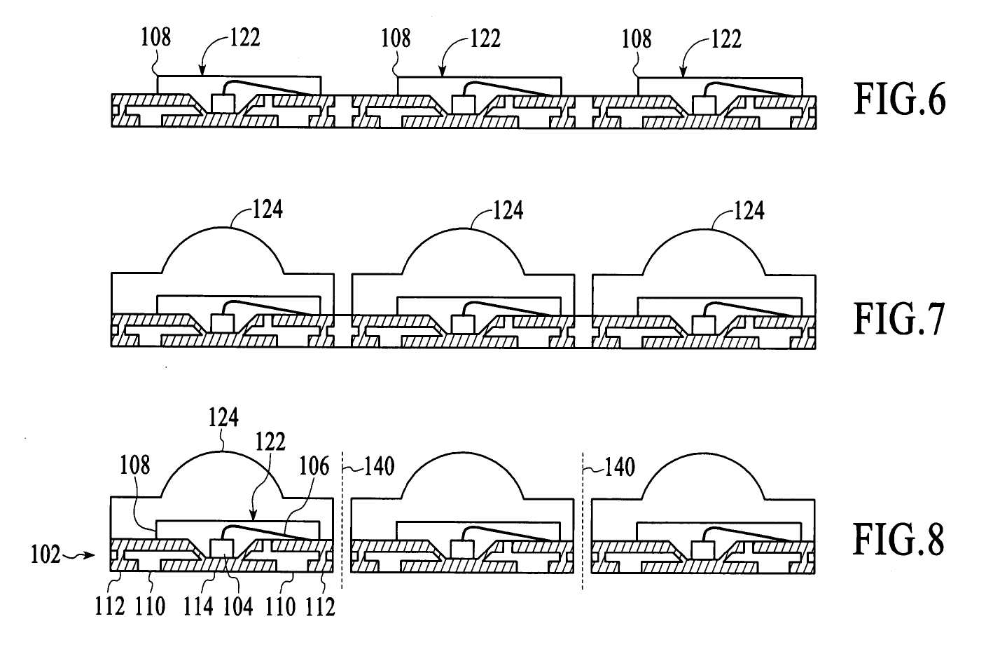

A PCB-based surface mount LED device with a silicone-based encapsulation structure can be formed starting with a PCB matrix. For example, FIG. 3 depicts an example of a PCB substrate matrix 132 with insulating material 110 and 134, conductors 112, and die pads 116. LED die 104 are attached to the PCB matrix at the die pads. The conductive wires 106 are then bonded between the LED die and the corresponding conductors (i.e., leads). FIG. 4 depicts LED die attached to the die pads and conductive wires bonded between the LED die and the conductors. The silicone-based encapsulation structure 108 is then created over the LED die and the PCB structure to encapsulate the LED die, the conductive wire, and the wire bonds. FIG. 5 depicts an example of PCB-based surface mount LED devices in which the silicone-based encapsulation structures include integrated lens structures. In an alternative embodiment as depicted in FIG. 6, the silicone-based encapsulation structures do not include an integrated lens structures. As shown in FIG. 6, the silicone-based encapsulation structures are formed with flat tops. When the silicone-based encapsulation structures do not include an integrated lens structure, lens structures 124 can be attached on top of the silicone-based encapsulation structures as depicted in FIG. 7. Finally, the PCB-based surface mount LED devices are separated from each other into individual devices in a singulation process as depicted by the dashed lines 140 in FIG. 8.

A lens may manipulate and/or focus light in different ways or directions than those depicted in FIGS. 1-8. For example, light may be emitted at different angles (e.g., forty-five or ninety degrees relative to the plane of the PCB matrix.

PCB-based surface mount LED devices with silicone-based encapsulation structures are suitable for small footprint and high volume production because PCB-substrates enable a small pitch layout of the light emitting devices.

Although specific embodiments of the invention have been described and illustrated, the invention is not to be limited to the specific forms or arrangements of parts so described and illustrated. The scope of the invention is to be defined by the claims appended hereto and their equivalents.

1. A light emitting device comprising:
a printed circuit board (PCB) substrate;
alight emitting diode (LED) die attached to the PCB substrate; and
a silicone-based encapsulation structure, wherein the LED die is encapsulated between the silicon-based encapsulation structure and the PCB substrate and wherein the silicone-based encapsulation structure includes a lens.

2. The light emitting device of claim 1 wherein the silicone-based encapsulation structure is formed of an optical grade silicone-based material.

3. (canceled)

4. (canceled)

5. (canceled)

6. (canceled)

7. (canceled)

8. (canceled)

9. The light emitting device of claim 1 wherein the PCB substrate includes surface mount-compatible leads.

10. A light emitting device comprising:
a printed circuit board (PCB) substrate having surface mount-compatible leads;
a light emitting diode (LED) die attached to the PCB substrate and electrically connected to the surface mount-compatible leads; and
a silicone-based encapsulation structure configured to encapsulate the LED die between the silicone-based encapsulation structure and the PCB substrate, wherein the silicone-based encapsulation structure includes a lens.

11. The light emitting device of claim 10 wherein the silicone-based encapsulation structure is formed of an optical grade silicone-based material.

12. (canceled)

13. (canceled)

14. (canceled)

15. (canceled)

16. (canceled)

17. (canceled)

18. (canceled)

19. (canceled)

20. (canceled)

21. The light emitting device of claim 1 wherein the lens is configured as a dome.

22. The light emitting device of claim 10 wherein the lens is configured as a dome.
